(19) United States
(12) Patent Application Publication
(10) Pub. No.: US 2023/0025626 A1
(43) Pub. Date: Jan. 26, 2023

(54) METHOD AND APPARATUS FOR GENERATING PROCESS SIMULATION MODELS

(71) Applicant: SAMSUNG ELECTRONICS CO., LTD., Suwon-Si (KR)

(72) Inventors: SANGHOON MYUNG, GOYANG-SI (KR); HYOWON MOON, HWASEONG-SI (KR); YONGWOO JEON, SEOUL (KR); CHANGWOOK JEONG, HWASEONG-SI (KR); JAEMYUNG CHOE, SEOUL (KR)

(21) Appl. No.: 17/852,024

(22) Filed: Jun. 28, 2022

(30) Foreign Application Priority Data
Jul. 20, 2021 (KR) 10-2021-0095160

(51) Int. Cl. G06F 30/27

(52) U.S. Cl. CPC G06F 30/27

(57) ABSTRACT

A method of generating a simulation model based on simulation data and measurement data of a target includes classifying weight parameters, included in a pre-learning model learned based on the simulation data, as a first weight group and a second weight group based on a degree of significance, retraining the first weight group of the pre-learning model based on the simulation data, and training the second weight group of a transfer learning model based on the measurement data, wherein the transfer learning model includes the first weight group of the pre-learning model retrained based on the simulation data.

### CROSS-REFERENCE TO RELATED APPLICATION

This application is based on and claims priority under 35 U.S.C. § 119 to Korean Patent Application No. 10-2021-0095160, filed on Jul. 20, 2021 in the Korean Intellectual Property Office, the disclosure of which is incorporated by reference herein in its entirety.

### BACKGROUND

### 1. Field

The present disclosure relates to a method and apparatus for generating a process simulation model. More particularly, the present disclosure relates to a method and apparatus for generating a process simulation model, which corrects a difference between measurement data and a simulation result of a process through a transfer learning model which has classified and learned weight parameters based on a degree of association.

### 2. Description of the Related Art

A neural network refers to a computational architecture obtained by modeling a biological brain. Recently, as neural network technology advances, research has been performed for analyzing input data to extract valid information by using a neural network device in various kinds of electronic systems.

In order to improve the performance of a simulation of a semiconductor process, engineers have conventionally performed a calibration operation by directly adjusting parameters based on physical knowledge, and research has been performed into applying neural network technology to improve the performance of the simulation of semiconductor processes. However, research into applying deep learning so as to decrease a difference between simulation data and real measurement data is insufficient.

### SUMMARY

According to an aspect of the teachings of the present disclosure, an apparatus classifies and processes weight data so as to reduce a difference between simulation data and measurement data in a process of processing a simulation of a semiconductor process through deep learning.

According to an aspect of the present disclosure, a method of generating a simulation model based on simulation data and measurement data of a target includes classifying weight parameters, included in a pre-learning model learned based on the simulation data, as a first weight group and a second weight group based on a degree of significance; and retraining the first weight group of the pre-learning model based on the simulation data, and training the second weight group of a transfer learning model based on the measurement data. The transfer model includes the first weight group of the pre-learning model retrained based on the simulation data.

According to another aspect of the present disclosure, a method of generating a simulation model based on simulation data and measurement data of a target includes generating a common model, learning a common feature of a first characteristic and a second characteristic based on simulation data, and generating a first pre-learning model inferring the first characteristic and a second pre-learning model inferring the second characteristic based on the common model. The method also includes classifying weight parameters, included in the first pre-learning model, as a first weight group and a second weight group based on the first characteristic and a degree of association; initializing weight parameters included in the second weight group and retraining the first pre-learning model and the second pre-learning model based on the first weight group and the simulation data; retraining the second pre-learning model based on the second weight group and the simulation data; training a first transfer learning model corresponding to the first pre-learning model based on the first weight group and measurement data of the first characteristic; and training a second transfer learning model corresponding to the second pre-learning model based on the first transfer learning model.

According to another aspect of the present disclosure, a neural network device includes a memory configured to store a neural network program and a processor configured to execute the neural network program stored in the memory. According to another aspect of the present disclosure, the processor is configured to execute the neural network program to classify weight parameters, included in a pre-learning model learned based on simulation data, as a first weight group and a second weight group based on a degree of significance, to retrain the first weight group of the pre-learning model based on the simulation data, and to train the second weight group of a transfer learning model based on measurement data. The transfer learning model includes the first weight group of the pre-learning model retrained based on the simulation data.

### BRIEF DESCRIPTION OF THE DRAWINGS

Embodiments of the inventive concept(s) described herein will be more clearly understood from the following detailed description taken in conjunction with the accompanying drawings in which:

FIG. 1 illustrates a process simulation system according to an embodiment;

FIG. 2 is a diagram for describing a transfer learning model for a process simulation, according to an embodiment;

FIG. 3 illustrates an electronic system according to an embodiment;

FIG. 4 illustrates an electronic system according to an embodiment;

FIG. 5 illustrates a structure of a convolutional neural network as an example of a neural network structure;

FIG. 6A and FIG. 6B are diagrams for describing a convolution operation of a neural network;

FIG. 7 is a diagram of a learning process of a process simulation model according to an embodiment;

FIG. 8 is a diagram of a learning process of a process simulation model according to an embodiment;

FIG. 9 is a flowchart of a method of generating a process simulation model, according to an embodiment;

FIG. 10 is a flowchart of a method of generating a process simulation model, according to an embodiment;

FIG. 11 is a block diagram illustrating an integrated circuit and an apparatus including the same, according to an embodiment; and

FIG. 12 is a block diagram illustrating a system including a neural network device, according to an embodiment.

### DETAILED DESCRIPTION OF THE EMBODIMENTS

Hereinafter, embodiments will be described in detail with reference to the accompanying drawings.

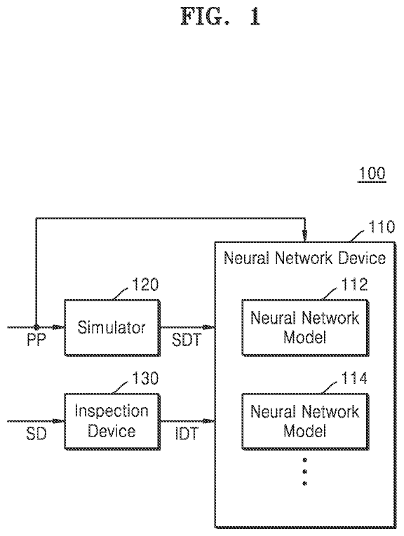

FIG. 1 illustrates a process simulation system 100 according to an embodiment.

The process simulation system 100 may include a neural network device 110, a simulator 120, and an inspection device 130. In addition, the process simulation system 100 may further include general-use elements such as a memory, a communication module, a video module, a three-dimensional (3D) graphics core, an audio system, a display driver, a graphics processing unit (GPU), and a digital signal processor (DSP). Examples of a video module include a camera interface, a joint photographic experts group (JPEG) processor, a video processor, or a mixer.

The neural network device 110 may analyze input data on the basis of a neural network to extract valid information and may determine a peripheral situation on the basis of the extracted information or may control elements of an electronic device equipped with the neural network device 110. For example, the neural network device 110 may model a target in a computing system or may be applied to a simulator, a drone, an advanced drivers assistance system (ADAS), a smart television (TV), a smartphone, a medical device, a mobile device, an image display device, an inspection device, and an Internet of things (IoT) device. Moreover, the neural network device 110 may be equipped in one of these or various other kinds of electronic devices.

The neural network device 110 may generate a neural network, or train (or learn) the neural network, or may perform an operation of the neural network on the basis of received input data and may generate an information signal on the basis of an operation result or may retrain the neural network. The neural network device 110 may include a hardware accelerator for executing the neural network. The hardware accelerator may correspond to, for example, a neural processing unit (NPU), a tensor processing unit (TPU), and a neural engine, which are dedicated modules for executing the neural network, but is not limited thereto.

The neural network device 110 according to an embodiment may execute a plurality of neural network models 112 and 114. The neural network model 112 may denote a deep learning model which is trained and performs a certain target operation such as a process simulation or image classification. The neural network model 112 may include a neural network model which is used to extract an information signal desired by the process simulation system 100. For example, the neural network model 112 may include at least one of various kinds of neural network models such as a convolutional neural network (CNN), a region with convolutional neural network (R-CNN), a region proposal network (RPN), a recurrent neural network (RNN), a stacking-based deep neural network (S-DNN), a state-space dynamic neural network (S-SDNN), a deconvolution network, a deep belief network (DBN), a restricted Boltzmann machine (RBM), a fully convolutional network, a long short-term memory (LSTM) network, a classification network, a generative adversarial network (GAN), a transformer, and an attention network.

The neural network model 112 may be trained and generated in a learning device, and the neural network model 112, which is trained, may be executed by the neural network device 110. An example of a learning device is a server which learns a neural network on the basis of a high amount of input data. Hereinafter, in an embodiment, the neural network model 112 may denote a neural network where configuration parameters (for example, a network topology, a bias, a weight, etc.) are determined through learning. Configuration parameters of the neural network model 112 may be updated through relearning in the learning device, and the neural network model 112, which is updated, may be applied to the neural network device 110.

The simulator 120 may construe and simulate physical phenomena such as the electrical, mechanical, and physical characteristics of a semiconductor device. Input data PP of the simulator 120 may include an input variable and environment information required by a simulation. The input variable may be used as an input variable of a model used by a process simulator. The environment information may include factors (for example, simulation flow, input/output information about each simulator, etc.) in addition to the input variable which has to be set for executing a simulation by using each simulator.

The simulator 120 may simulate a characteristic of a circuit or a process and a device of the semiconductor device and may provide output data SDT, which is a simulation result. For example, the simulator 120 may simulate each process step by using one or more process simulation models on the basis of a material, a structure, and process input data. One or more process steps may include an oxidation process, a photoresist coating process, an exposure process, a development process, an etching process, an ion implantation process, a diffusion process, a chemical vapor deposition process, and a metallization process. The simulator 120 may simulate at least one device to output device characteristic data by using a predetermined device simulation device, on the basis of a simulation result of each process step.

The inspection device 130 or a test device may measure a characteristic of a semiconductor device SD and may generate measurement data IDT. The measurement data IDT of the semiconductor device SD generated by the inspection device 130 may include data corresponding to the output data SDT of the simulator 120.

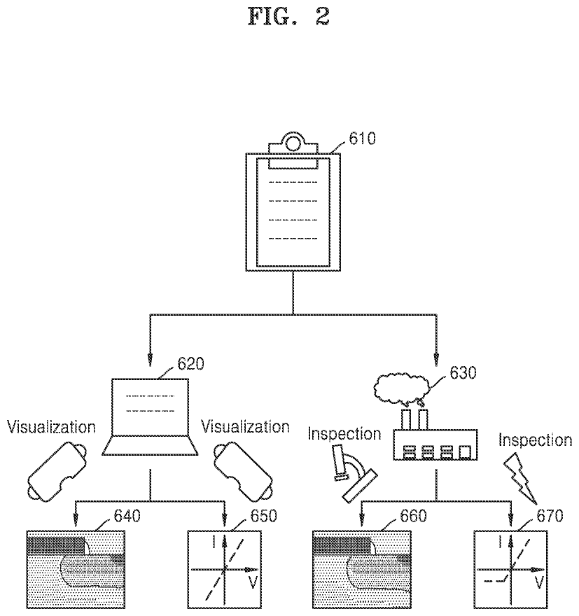

FIG. 2 is a diagram of a transfer learning model for a process simulation, according to an embodiment.

Referring to FIG. 2, a process simulation system may perform a process simulation 620 or an experiment 630 on the basis of an input variable and environment information 610 needed for a process. The input variable may be used as an input variable of a model used by a process simulator. The environment information 610 may include factors (for example, simulation flow, input/output information about each simulator, etc.) in addition to the input variable which has to be set for executing a simulation by using each simulator.

The process simulation system may construe and simulate physical phenomena such as the electrical, mechanical, and physical characteristics of a semiconductor device in an operation of performing the process simulation 620 to generate a simulation result such as a doping profile 640 or voltage-current characteristic data 650 of the semiconductor device.

The process simulation system may perform measurement on a semiconductor device manufactured in the experiment 630 or an actual process and may generate the doping profile 640 or the voltage-current characteristic data 650 of the semiconductor device.

In a case where the process simulation system performs the process simulation 620 or the experiment 630 on the basis of the same input variable and environment information for generating the same semiconductor device, the doping profile 640 or the voltage-current characteristic data 650 generated through the process simulation 620 may differ from a doping profile 660 or voltage-current characteristic data 670 generated as a result of the experiment 630.

When a characteristic of each process is changed or process generation varies, a difference may occur in output data including a doping profile or voltage-current characteristic data. In a transfer learning model for a process simulation, when input data is the same and output data differs, measurement data of a learning target may be needed, but the cost may increase or measurement may be impossible.

For example, in the voltage-current characteristic data 670 of the semiconductor device, measurement may be relatively easy, but the high cost may be consumed for obtaining the doping profile 660 of the semiconductor device and measurement may be difficult or impossible. Therefore, when there is small measurement data or there is no measurement data, a method of generating a transfer learning model may be needed.

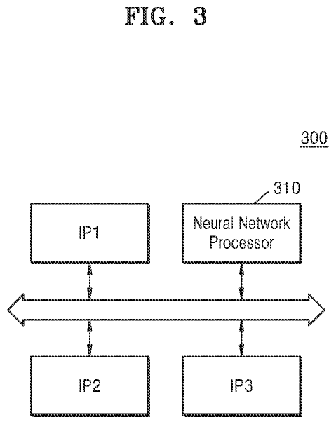

FIG. 3 illustrates an electronic system 300 according to an embodiment.

The electronic system 300 may analyze input data on the basis of a neural network in real time to extract valid information and may determine a situation on the basis of the extracted information or may control elements of an electronic device equipped with the electronic system 300. For example, the electronic system 300 may be applied to a robot device such as a drone or an ADAS, a smart TV, a smartphone, a medical device, a mobile device, an image display device, an inspection device, and an IoT device. Moreover, the electronic system 300 may be equipped in one of these or various other kinds of electronic devices.

The electronic system 300 may include at least one intellectual property (IP) block and a neural network processor 310. An IP block may be a unit of logic, a cell or an integrated circuit that may be reusable and may be subject to intellectual property of a single party as a unique unit of logic, cell or integrated circuit. A discrete circuit such as an IP block may have a discrete combination of structural circuit components, and may be dedicated in advance to performing particular functions. For example, the electronic system 300 may include a first IP block IP1, second IP block IP2 and third IP block IP3 and the neural network processor 310.

The electronic system 300 may include various kinds of IP blocks. For example, the IP blocks may include a processing unit, a plurality of cores included in the processing unit, a multi-format codec (MFC), a video module (for example, a camera interface, a JPEG processor, a video processor, or a mixer), a 3D graphics core, an audio system, a driver, a display driver, a volatile memory, a non-volatile memory, a memory controller, an input/output interface block, or a cache memory. Each of the first IP block IP1, the second IP block IP2 and the third IP block IP3 may include at least one of the various kinds of IP blocks.

Technology for connecting IP blocks may include a connection based on a system bus. For example, an advanced microcontroller bus architecture (AMBA) protocol of Advanced RISC Machine (ARM) may be applied as a standard bus protocol. Bus types of the AMBA protocol may include advanced high-performance bus (AHB), advanced peripheral bus (APB), advanced extensible interface (AXI), AXI4, and AXI coherency extensions (ACE). Among the bus types described above, AXI may be an interface protocol between IP blocks and may provide a multiple outstanding address function and a data interleaving function. In addition, other types of protocol, such as uNetwork of SONICs Inc., CoreConnect of IBM Inc., or open core protocol of OCP-IP, may be applied to the system bus.

The neural network processor 310 may generate a neural network, train or learn the neural network, or perform an arithmetic operation on the basis of input data received thereby and may generate an information signal on the basis of a performance result or may retrain the neural network. Models of the neural network may include various kinds of models such as GoogleNet, AlexNet, CNN such as a VGG network, R-CNN, RPN, RNN, S-DNN, S-SDNN, a deconvolution network, DBN, RBM, a fully convolutional network, an LSTM network, a classification network, a deep Q-network (DQN), and distribution reinforcement learning, but are not limited thereto. The neural network processor 310 may include one or more processors for performing an arithmetic operation based on the models of the neural network. Also, the neural network processor 310 may include a separate memory for storing programs corresponding to the models of the neural network. The neural network processor 310 may be referred to as a neural network processing device, a neural network integrated circuit, a neural network processing unit (NPU), or a deep learning device.

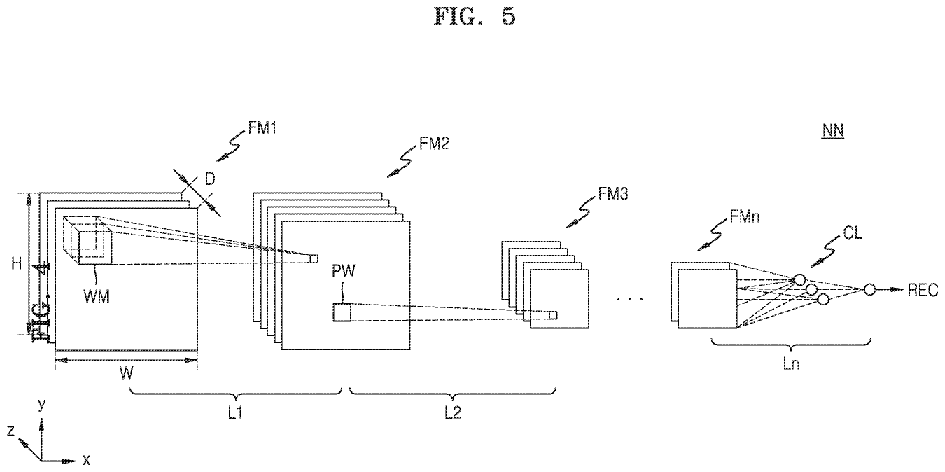

The neural network processor 310 may receive various kinds of pieces of input data from at least one IP block through the system bus and may generate the information signal on the basis of the input data. For example, the neural network processor 310 may perform a neural network operation on the input data to generate the information signal, and the neural network operation may include a convolution operation. The convolution operation of the neural network processor 310 is described in more detail with reference to FIG. 5A and FIG. 5B. The information signal generated by the neural network processor 310 may include at least one of various kinds of recognition signals such as a voice recognition signal, an object recognition signal, an image recognition signal, and a biometric information recognition signal. For example, the neural network processor 310 may receive, as input data, frame data included in a video stream and may generate a recognition signal, corresponding to an object included in an image represented by the frame data, from the frame data. However, the teachings of the present disclosure are not limited thereto, and the neural network processor 310 may receive various kinds of input data and may generate a recognition signal based on the input data.

In the electronic system 300 according to an embodiment, the neural network processor 310 may perform a separate process on a weight value included in kernel data used for a convolution operation to calibrate the kernel data. For example, the neural network processor 310 may classify and initialize or relearn weight values in a learning process.

As described above, in the electronic system 300 according to an embodiment, by performing a separate process on weight values of kernel data used for a convolution operation, process simulation data may be calibrated to be closer to measurement data. Moreover, the accuracy of the neural network processor 310 may increase. Simulation described herein may include, but is not limited to one or more of semiconductor process parameters and characteristic data of a semiconductor device manufactured based on the semiconductor process parameters.

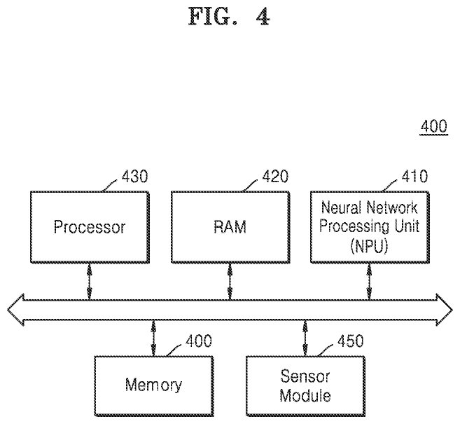

FIG. 4 illustrates an electronic system 400 according to an embodiment.

Particularly, FIG. 4 illustrates a more detailed embodiment of the electronic system 300 illustrated in FIG. 3. In the electronic system 400 of FIG. 4, descriptions which are the same as or similar to the descriptions of FIG. 3 are omitted.

The electronic system 400 may include an NPU 410, RAM 420 (random access memory), a processor 430, a memory 440, and a sensor module 450. The NPU 410 may be an element corresponding to the neural network processor 310 of FIG. 2.

The RAM 420 may temporarily store programs, data, or instructions. For example, programs and/or data stored in the memory 440 may be temporarily loaded into the RAM 420 on the basis of booting code or control by the processor 430. The RAM 420 may be implemented with a memory such as dynamic RAM (DRAM) or static RAM (SRAM).

The processor 430 may control an overall operation of the electronic system 400, and for example, the processor 430 may be a central processing unit (CPU). The processor 430 may include one processor core (a single core), or may include a plurality of processor cores (a multi-core). The processor 430 may process or execute the programs and/or the data each stored in the RAM 420 and the memory 440. For example, the processor 430 may execute the programs stored in the memory 440 to control functions of the electronic system 400.

The memory 440 may be a storage for storing data, and for example, may store an operating system (OS), various kinds of programs, and various pieces of data. The memory 440 may include DRAM, but is not limited thereto. The memory 440 may include at least one of a volatile memory and a non-volatile memory. The non-volatile memory may include read only memory (ROM), programmable ROM (PROM), electrically programmable ROM (EPROM), electrically erasable and programmable ROM (EEPROM), flash memory, phase-change RAM (PRAM), magnetic RAM (MRAM), resistive RAM (RRAM), ferroelectric RAM (FRAM), etc. The volatile memory may include DRAM, SRAM, synchronous DRAM (SDRAM), etc. Also, in an embodiment, the memory 440 may include at least one of a hard disk drive (HDD), a solid state drive (SSD), a compact flash (CF) memory, a secure digital (SD) memory, a micro-SD memory, a mini-SD memory, an extreme digital (xD) memory, and a memory stick.

The sensor module 450 may collect peripheral information about the electronic system 400. The sensor module 450 may sense or receive measurement data of a semiconductor device from the outside of the electronic system 400.

In the electronic system 400 according to an embodiment, the NPU 410 may perform a separate process on a weight value included in kernel data used for a convolution operation to calibrate the kernel data. For example, the NPU 410 may classify and initialize or relearn weight values in a learning process.

As described above, in the electronic system 400 according to an embodiment, by performing a separate process on weight values of kernel data used for a convolution operation, process simulation data may be calibrated to be closer to measurement data. Moreover, the accuracy of the NPU 410 may increase.

FIG. 5 illustrates a structure of a CNN as an example of a neural network structure.

A neural network NN may include a plurality of layers, for example, first layer L1 to n^{th} layer Ln. Each of the plurality of layers L1 to Ln may be a linear layer or a nonlinear layer, and in an embodiment, a combination of at least one linear layer and at least one nonlinear layer may be referred to as one layer. For example, the linear layer may include a convolution layer and a fully connected layer, and the nonlinear layer may include a pooling layer and an activation layer.

For example, the first layer L1 may be a convolution layer, the second layer L2 may be a pooling layer, and the n^{th} layer Ln may be an output layer and may be a fully connected layer. The neural network NN may further include an activation layer, and moreover, may further include a layer for performing a different kind of operation.

Each of the plurality of layers L1 to Ln may receive, as an input feature map, input data (for example, an image frame) or a feature map generated in a previous layer and may perform an arithmetic operation on the input feature map to generate an output feature map or a recognition signal REC. In this case, the feature map may denote data where various features of input data are expressed. A plurality of feature maps (for example, first, second, and n^{th} feature maps) FM1, FM2, and FMn may have, for example, a two-dimensional (2D) matrix form or a 3D matrix (or tensor) form. The feature maps FM1, FM2, and FMn may have a width W (or a column), a height H (or a row), and a depth D and may respectively correspond to an x axis, a y axis, and a z axis of coordinates. In this case, the depth D may be referred to as the number of channels.

The first layer L1 may perform convolution between the first feature map FM1 and the weight kernel WK to generate the second feature map FM2. The weight kernel WK may filter the first feature map FM1 and may be referred to as a filter or a map. A depth (i.e., the number of channels) of the weight kernel WK may be the same as a depth (i.e., the number of channels) of the first feature map FM1 and may perform convolution between the same channels of the weight kernel WK and the first feature map FM1. The weight kernel WK may be shifted by a crossing manner by using the first feature map FM1 as a sliding window. The amount of shift may be referred to as “a stride length” or “a stride”. While each shift is being performed, each of weight values included in the weight kernel WK may be multiplied by all pixel data and summated in a region overlapping the first feature map FM1. Pieces of extraction data of the first feature map FM1 in a region where each of weight values included in the weight kernel WK overlaps the first feature map FM1 may be referred to as extraction data. As convolution between the first feature map FM1 and the weight kernel WK is performed, one channel of the second feature map FM2 may be generated. In FIG. 3, one weight kernel WK is illustrated, but substantially, convolution between a plurality of weight maps and the first feature map FM1 may be performed, thereby generating a plurality of channels of the second feature map FM2. In other words, the number of channels of the second feature map FM2 may correspond to the number of weight maps.

The second layer L2 may vary a spatial size of the second feature map FM2 through pooling to generate the third feature map FM3. Pooling may be referred to as sampling or down-sampling. A 2D pooling window PW may be shifted in the second feature map FM2 by units of sizes of the pooling window, and a maximum value (or an average value of pieces of pixel data) among pieces of pixel data in a region overlapping the pooling window PW may be selected. Therefore, the third feature map FM3 where a spatial size has varied may be generated from the second feature map FM2. The number of channels of the third feature map FM3 may be the same as the number of channels of the second feature map FM2.

The n^{th} layer Ln may combine features of the nth feature map FMn to classify a class CL of input data. Also, the n^{th} layer Ln may generate the recognition signal REC corresponding to a class. In an embodiment, the input data may correspond to frame data included in a video stream, and the n^{th} layer Ln may extract a class corresponding to an object included in an image represented by frame data based on the n^{th} feature map FMn provided from a previous layer to recognize the object and may generate the recognition signal REC corresponding to the recognized object.

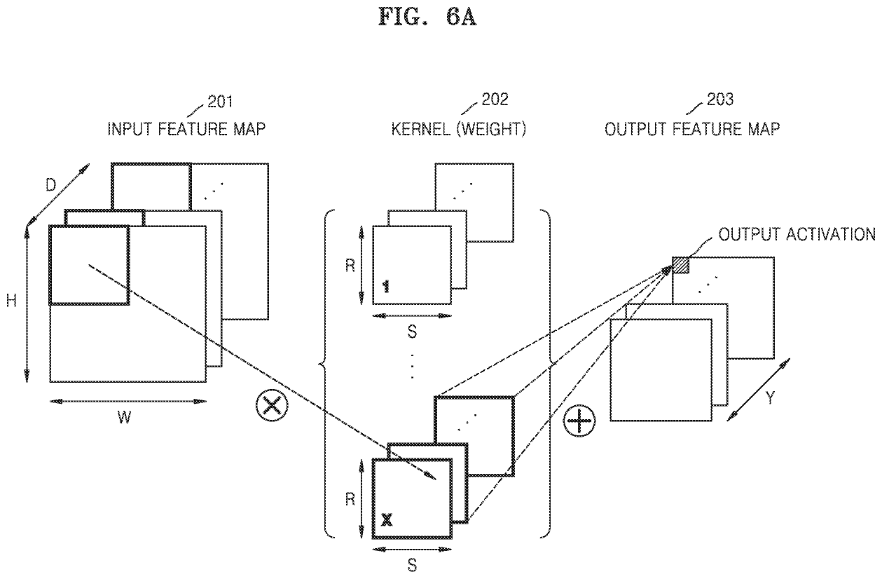

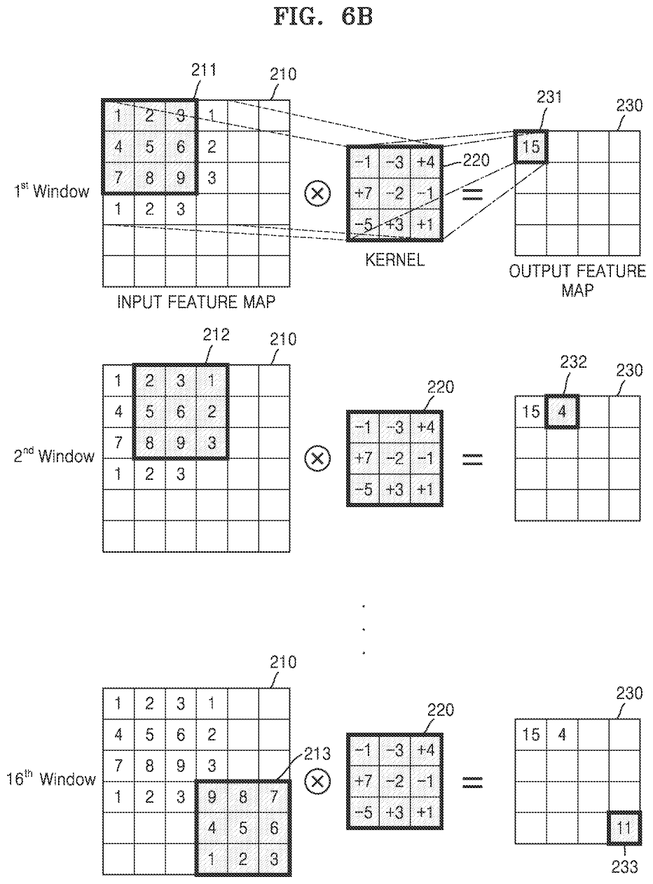

FIG. 6A and FIG. 6B are diagrams for describing a convolution operation of a neural network.

Referring to FIG. 6A, input feature maps 201 may include D number of channels, and an input feature map of each of the channels may have an H row, W column size (where D, H, and W are natural numbers). Each of kernels 202 may have an R row, S column size, and the number of channels of the kernels 202 may correspond to the number of channels (or a depth) D of the input feature maps 201 (where R and S are natural numbers). Output feature maps 203 may be generated by performing a 3D convolution operation between the input feature maps 201 and the kernels 202 and may include Y (where Y is a natural number) number of channels based on a convolution operation.

A process of generating an output feature map through a convolution operation between one input feature map and one kernel is described with reference to FIG. 6B, and the 2D convolution operation described above with reference to FIG. 5 may be performed between input feature maps 201 of all channels and kernels of all channels, thereby generating output feature maps 203 of all channels.

Referring to FIG. 6B, for convenience of description, it may be assumed that an input feature map 210 has a 6×6 size, an original kernel 220 has a 3×3 size, and an output feature map 230 has a 4×4 size. However, the present embodiment is not limited to these sizes, and a neural network may be implemented with feature maps and kernels having various sizes. Also, values defined in the input feature map 210, the original kernel 220, and the output feature map 230 are merely exemplified values, and embodiments are not limited thereto.

The original kernel 220 may perform a convolution operation while sliding by units of windows having a 3×3 size in the input feature map 210. The convolution operation may denote an arithmetic operation of calculating each feature data of the output feature map 230 by summating values obtained by multiplying each feature data of an arbitrary window of the input feature map 210 by weight values of each corresponding position in the original kernel 220. Pieces of data included in a window of the input feature map 210 and multiplied by weight values may be referred to as extraction data extracted from the input feature map 210. In detail, the original kernel 220 may first perform a convolution operation on first extraction data 211 of the input feature map 210. That is, pieces of feature data “1, 2, 3, 4, 5, 6, 7, 8, and 9” of the first extraction data 211 may be respectively multiplied by weight values “−1, −3, 4, 7, −2, −1, −5, 3, and 1” of the original kernel 220 corresponding thereto, and thus, −1, −6, 12, 28, −10, −6, −35, 24, and 9 may be obtained. Subsequently, 15, which is a result obtained by summating the obtained values “−1, −6, 12, 28, −10, −6, −35, 24, and 9”, may be calculated, and feature data 231 of the first row, first column of the output feature map 230 may be determined as 15. Here, the feature data 231 of the first row, first column of the output feature map 230 may correspond to the first extraction data 211. In this manner, 4, which is feature data 232 of the first row, second column of the output feature map 230, may be determined by performing a convolution operation between second extraction data 212 of the input feature map 210 and the original kernel 220. Finally, 11, which is feature data 233 of the fourth row, fourth column of the output feature map 230, may be determined by performing a convolution operation between the original kernel 220 and sixteenth extraction data 213, which is last extraction data of the input feature map 210.

In other words, a convolution operation between one input feature map 210 and one original kernel 220 may be processed by repeatedly performing multiplication of extraction data of the input feature map 210 and corresponding weight values of the original kernel 220 and addition of multiplication results, and the output feature map 230 may be generated as a result of the convolution operation.

Referring to FIG. 6A and FIG. 6B in conjunction with FIG. 1, in the neural network device 110 according to an embodiment, in a convolution operation, the neural network device 110 may classify and initialize or retrain weight values of kernel data included in a plurality of neural network models 112, 114, . . . . The neural network device 110 may perform a separate process on weight values of kernel data used for a convolution operation. Therefore, process simulation data may be calibrated to be closer to measurement data, thereby increasing the accuracy of the neural network device 110.

For example, the neural network device 110 may sort weight values “−1, −3, 4, 7, −2, −1, −5, 3, and 1” of the original kernel 220 in order of size, classify a largest number “7” as a significant weight value, and generate a mask filter for filtering 7.

A method of generating a process simulation model based on measurement data and simulation data of the neural network device 110 and a neural network device for the method, according to an embodiment, are described in more detail with reference to the drawings.

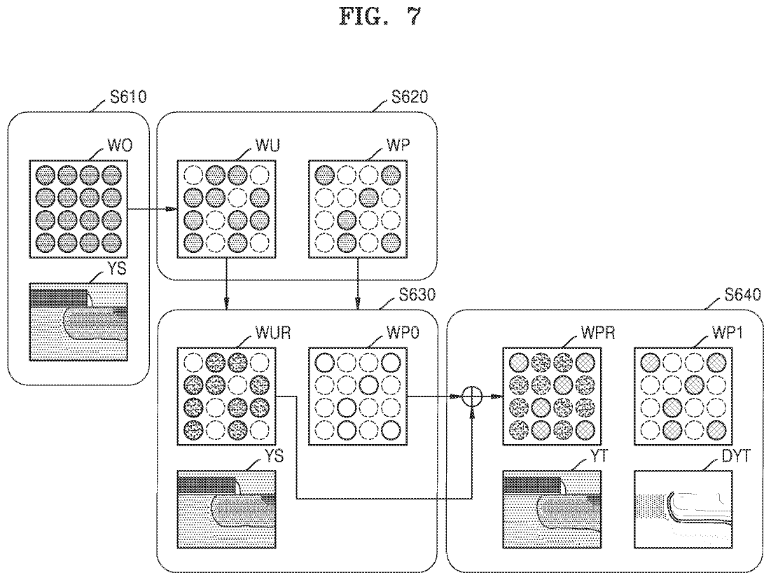

FIG. 7 is a diagram of a learning process of a process simulation model according to an embodiment.

Referring to FIG. 7, when there are a high amount of simulation data and a low amount of real measurement data, a process simulation system may perform inductive transfer learning.

A learning process of the process simulation model may include a pre-learning operation (S610), a weight classification operation (S620), a retraining operation (S630), and a calibration operation (S640).

The process simulation system may learn a high amount of process simulation data for outputting a doping profile by using a process parameter as an input in the pre-learning operation (S610). The process simulation system may learn the process simulation data to generate a pre-learning weight value WO. The process simulation system may infer a first doping profile YS through a pre-learning model.

The process simulation system may classify weight parameters based on an influence on inferring the first doping profile YS in a process simulation learning process in the weight classification operation (S620). The process simulation system may use mask alignment for classifying the weight parameters.

The process simulation system may sort values of the weight parameters in descending order or ascending order of values and may classify a first weight group WU and a second weight group WP based on a size of sorted data. For example, the sorting of the weight parameters may be in ascending order thereof based on sizes of the weight parameters. For example, the process simulation system may classify some weight parameters, included in upper 10% in size among the weight parameters, as the first weight group WU and the other weight parameters as the second weight group WP.

The process simulation system may sort the values of the weight parameters in descending order or ascending order of values, select a reference weight value in a period where a value of the sorted data varies rapidly or a degree of variation is large, and classify some weight parameters, which are greater than or equal to the reference weight value, as the first weight group WU and the other weight parameters as the second weight group WP. For example, the classifying of the weight parameters may include extracting, e.g., the first weight group WU, from the weight parameters based on sizes of the weight parameters. A criterion for classifying a weight group is not limited to use of reference weight values, and weight values having high significance may be extracted through various methods.

The process simulation system may initialize weight parameters, corresponding to the second weight group WP in the pre-learning weight value WO of the pre-learning model, to 0 in the retraining operation (S630).

The process simulation system may retrain weight parameters corresponding to the first weight group WU in the pre-learning weight value WO of the pre-learning model. The process simulation system may perform learning on only the first weight group WU in a state where the second weight group WP is initialized to 0, based on simulation data learned in the pre-learning operation (S610). The process simulation system may train a transfer learning model based on real measurement data in the calibration operation (S640). The process simulation system may apply data of the first weight group WU, retrained in the retraining operation (S630), to the transfer learning model. The process simulation system may perform learning on the second weight group WP of the transfer learning model based on the real measurement data. As a result, a method of generating a simulation model based on simulation data and measurement data of a target may include training the second weight group of a transfer learning model based on the measurement data at S640, wherein the transfer learning model includes the first weight group retrained at S630.

The process simulation system may perform a normalization process on values of weight parameters of the second weight group WP. The process simulation system may solve an under-suitability or over-suitability problem by using the normalization process. For example, a main physical characteristic of a simulation may be reflected in the first weight group WU relearned in the transfer learning model. As a result, in the second weight group WP, it may be predicted that a variation is not large in a learning process. Therefore, when values of weight parameters of the second weight group WP are greater than or equal to a predetermined reference value, the process simulation system may determine an exception or attribute the values of the weight parameters of the second weight group WP to noise and may not reflect corresponding learning content.

For example, the normalization process may include L1 normalization or L2 normalization used in the machine learning field. The process simulation system may infer a second doping profile YT by using the transfer learning model. The process simulation system may update a difference between a transfer learning model, which has learned the real measurement data, and a transfer learning model which has learned the simulation data, and thus, may correct a difference between the simulation data and the measurement data in real time.

As set forth above, a method of generating a simulation model based on simulation data and measurement data of a target may include classifying, as at S620, weight parameters, included in a pre-learning model learned based on the simulation data, as a first weight group and a second weight group based on a degree of significance. The method may also include retraining, as at S630, the first weight group of the pre-learning model based on the simulation data. The method may further include training, as at S640, the second weight group of a transfer learning model based on the measurement data, wherein the transfer learning model includes the first weight group of the pre-learning model retrained based on the simulation data.

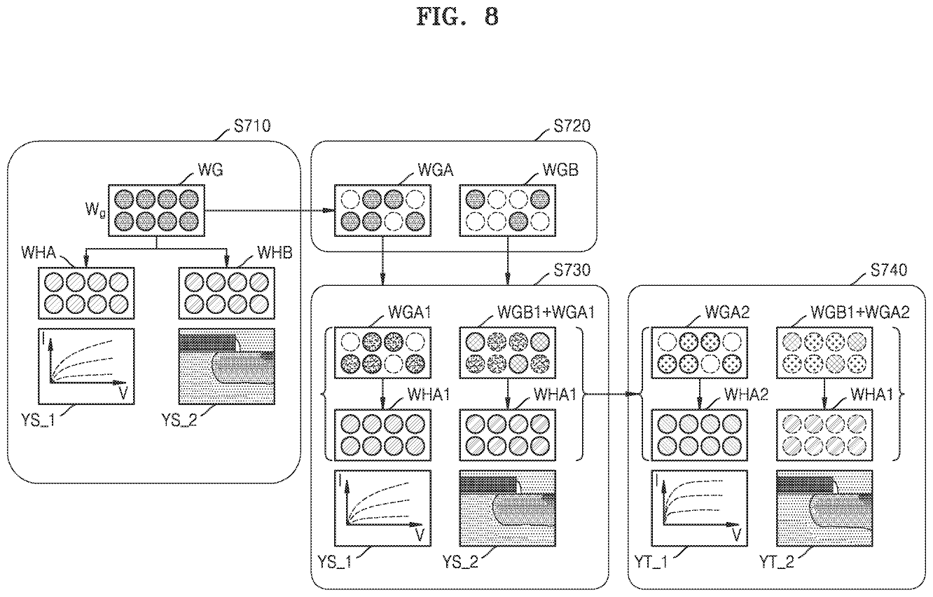

FIG. 8 is a diagram of a learning process of a process simulation model according to an embodiment.

Referring to FIG. 8, when there is a high amount of simulation data and there is no real measurement data, a process simulation system may perform dual inductive transfer learning.

A learning process of the process simulation model may include a pre-learning operation (S710), a weight classification operation (S720), a retraining operation (S730), and a calibration operation (S740).

The process simulation system may learn a high amount of process simulation data for outputting a doping profile or a voltage-current characteristic by using a process parameter as an input in the pre-learning operation (S710). The process simulation system may infer a doping profile, a voltage-current characteristic, or at least one piece of data of the other characteristics by using a pre-learning model. For example, a first characteristic inferred may be the voltage-current characteristic, and a second characteristic may be the doping profile.

The process simulation system may learn the process simulation data to generate a pre-learning weight value WG. The process simulation system may generate a first characteristic weight value WHA corresponding to the first characteristic and a second characteristic weight value WHB corresponding to the second characteristic.

The process simulation system may infer a first characteristic YS_1 and a second characteristic YS_2 by using the pre-learning model.

The process simulation system may classify weight parameters based on an influence on inferring the first characteristic YS_1 in a process simulation learning process in the weight classification operation (S720). The process simulation system may use mask alignment for classifying the weight parameters.

The process simulation system may sort values of the weight parameters in descending order or ascending order of values and may classify a first weight group WGA and a second weight group WGB based on a size of sorted data. For example, the process simulation system may classify some weight parameters, included in upper 10% in size among the weight parameters, as the first weight group WGA and the other weight parameters as the second weight group WGB. A criterion for classifying a weight group is not limited thereto, and weight values having high significance may be extracted through various methods.

The process simulation system may initialize weight parameters, corresponding to the second weight group WGB in the pre-learning weight value WG of the pre-learning model, to 0 in the retraining operation (S730).

The process simulation system may retrain weight parameters corresponding to the first weight group WGA in the pre-learning weight value WG for inferring the first characteristic YS_1 of the pre-learning model. The process simulation system may perform learning on only the first weight group WGA in a state where the second weight group WGB is initialized to 0, based on simulation data learned in the pre-learning operation (S710).

The process simulation system may retrain weight parameters corresponding to the second weight group WGB in the pre-learning weight value WG for inferring the second characteristic YS_2 of the pre-learning model.

The process simulation system may train a transfer learning model based on real measurement data in the calibration operation (S740). The process simulation system may apply data of the first weight group WU, relearned in the retraining operation (S730), to the transfer learning model.

The process simulation system may analyze and combine a difference between the first characteristic YS_1 inferred by the pre-learning model and a first correction characteristic YT_1 inferred by the transfer learning model and weight values corresponding to the second characteristic YS_2 inferred by the pre-learning model to infer a calibrated second correction characteristic YT_2.

For example, a first transfer learning model of the transfer learning model may infer the first correction characteristic YT_1, and a second transfer learning model may infer the second correction characteristic YT_2. The first transfer learning model may be configured to infer a voltage-current characteristic of a semiconductor device, and the second transfer learning model may be configured to infer a doping profile of the semiconductor device, by using semiconductor process parameters as inputs.

The process simulation system may update a difference between a transfer learning model, which has learned the real measurement data, and a transfer learning model which has learned the simulation data. Resultingly, the process simulation system may correct a difference between the simulation data and the measurement data in real time.

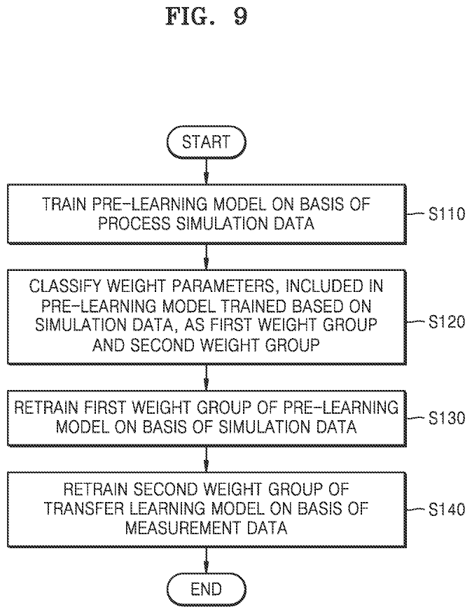

FIG. 9 is a flowchart of a method of generating a process simulation model, according to an embodiment.

In operation S110, the process simulation system may train a pre-learning model based on process simulation data. For example, the process simulation system may learn simulation data for outputting a doping profile by using a process parameter as an input. The process simulation system may learn the process simulation data to generate a pre-learning weight value. The process simulation system may infer a first doping profile by using the pre-learning model.

In operation S120, the process simulation system may classify weight parameters, included in the pre-learning model trained based on simulation data, as a first weight group and a second weight group. For example, the process simulation system may classify weight parameters based on an influence on inferring the first doping profile in a process simulation learning process and may determine that a degree of influence thereon is large as a weight value increases. The process simulation system may sort values of the weight parameters in descending order or ascending order of values and may classify the first weight group and the second weight group based on a size of sorted data. For example, the process simulation system may classify some weight parameters, included in upper 10% in size among the weight parameters, as the first weight group and the other weight parameters as the second weight group.

In operation S130, the process simulation system may retrain the first weight group of the pre-learning model based on the simulation data. The process simulation system may perform learning on only the first weight group in a state where the second weight group is initialized to 0, based on the simulation data learned in a pre-learning operation.

In operation S140, the process simulation system may retrain the second weight group of the transfer learning model based on the measurement data. The process simulation system may apply data of the first weight group, retrained in the retrain operation (S130), to the transfer learning model. The process simulation system may perform learning on the second weight group of the transfer learning model based on real measurement data. The process simulation system may perform a normalization process on values of weight parameters of the second weight group. For example, when values of weight parameters of the second weight group are greater than or equal to a predetermined reference value, the process simulation system may determine an exception or attribute the values of the weight parameters of the second weight group to noise and may not reflect corresponding learning content. For example, the normalization process may include L1 normalization or L2 normalization used in the machine learning field.

The process simulation system may infer a second doping profile by using the transfer learning model. The process simulation system may update a difference between a transfer learning model, which has learned the real measurement data, and a transfer learning model which has learned the simulation data. Resultingly, the process simulation system may correct a difference between the simulation data and the measurement data in real time.

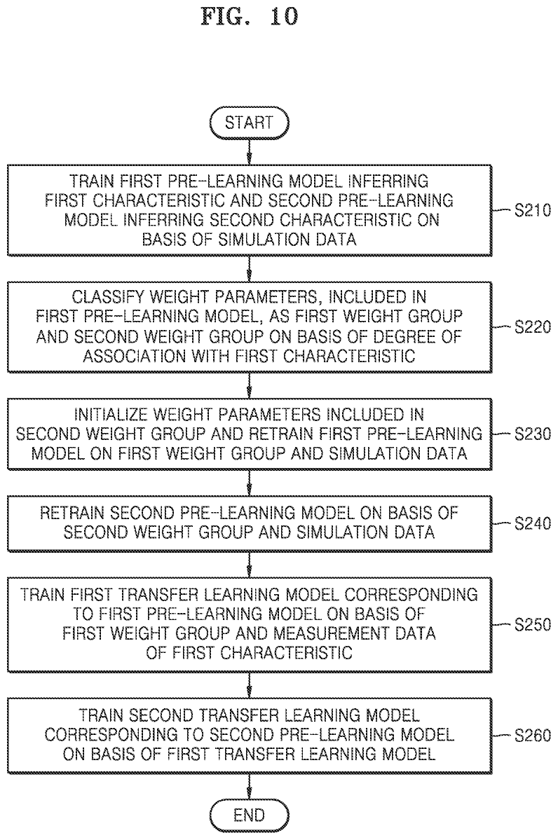

FIG. 10 is a flowchart of a method of generating a process simulation model, according to an embodiment.

Referring to FIG. 10, when there is a high amount of simulation data and there is no real measurement data, a process simulation system may perform dual inductive transfer learning which learns other associated simulation data and measurement data.

In operation S210, the process simulation system may train a first pre-learning model inferring a first characteristic and a second pre-learning model inferring a second characteristic based on the simulation data. The process simulation system may generate a common model which learns a common feature of the first characteristic and the second characteristic. The process simulation system may generate the first pre-learning model inferring the first characteristic and the second pre-learning model inferring the second characteristic, which are derived from the common model. For example, the first pre-learning model and the second pre-learning model may be models which are derived from the common model learned based on the same data and may be the same model where only inference targets differ. The process simulation system may learn a high amount of process simulation data for outputting a doping profile or a voltage-current characteristic by using a process parameter as an input. The process simulation system may infer a doping profile, a voltage-current characteristic, or at least one piece of data of the other characteristics by using a pre-learning model. For example, the first characteristic inferred may be the voltage-current characteristic, and the second characteristic may be the doping profile.

The process simulation system may learn the process simulation data to generate a pre-learning weight value. The process simulation system may generate a first characteristic weight value corresponding to the first characteristic and a second characteristic weight value corresponding to the second characteristic. The process simulation system may infer the first characteristic and the second characteristic by using the pre-learning model.

In operation S220, the process simulation system may classify weight parameters, included in the first pre-learning model, as a first weight group and a second weight group based on a degree of association with the first characteristic. The process simulation system may classify weight parameters based on an influence on inferring the first characteristic in a process simulation learning process. The process simulation system may use mask alignment for classifying the weight parameters.

The process simulation system may sort values of the weight parameters in descending order or ascending order of values and may classify the first weight group and the second weight group based on a size of sorted data. For example, the process simulation system may classify some weight parameters, included in upper 10% in size among the weight parameters, as the first weight group and the other weight parameters as the second weight group. A criterion for classifying a weight group is not limited thereto, and weight values having high significance may be extracted through various methods.

In operation S230, the process simulation system may initialize weight parameters included in the second weight group and may retrain the first pre-learning model on the first weight group and the simulation data. The process simulation system may initialize weight parameters, corresponding to the second weight group among pre-learning weight values of a pre-learning model, to 0.

The process simulation system may retrain weight parameters corresponding to the first weight group in the pre-learning weight value for inferring the first characteristic of the pre-learning model. The process simulation system may perform learning on only the first weight group in a state where the second weight group is initialized to 0, based on simulation data learned in the pre-learning operation (S210).

In operation S240, the process simulation system may retrain the second pre-learning model based on the second weight group and the simulation data. The process simulation system may retrain weight parameters corresponding to the second weight group in the pre-learning weight value for inferring the second characteristic of the pre-learning model.

In operation S250, the process simulation system may train a first transfer learning model corresponding to the first pre-learning model based on the first weight group and measurement data of the first characteristic. The process simulation system may train a transfer learning model based on real measurement data. The process simulation system may apply data of the first weight group, corresponding to the first characteristic retrained in the retrain operation (S240), to the transfer learning model.

In operation S260, the process simulation system may train a second transfer learning model corresponding to the second pre-learning model based on the first transfer learning model. The process simulation system may analyze and combine a difference between the first characteristic inferred by the pre-learning model and a first correction characteristic inferred by the transfer learning model and weight values corresponding to the second characteristic inferred by the pre-learning model to infer a calibrated second correction characteristic. For example, the training of the second transfer learning model may include generating the second transfer learning model based on a first pre-learning mode, variation data of a weight parameter of the first transfer learning model, and a second weight group of the second pre-learning model. The variation data may reflect, e.g., that a value of the sorted data varies rapidly or a that a degree of variation is large.

For example, a first transfer learning model of the transfer learning model may infer the first correction characteristic, and a second transfer learning model may infer the second correction characteristic.

The process simulation system may update a difference between a transfer learning model, which has learned the real measurement data, and a transfer learning model which has learned the simulation data. Resultingly, the process simulation system may correct a difference between the simulation data and the measurement data in real time.

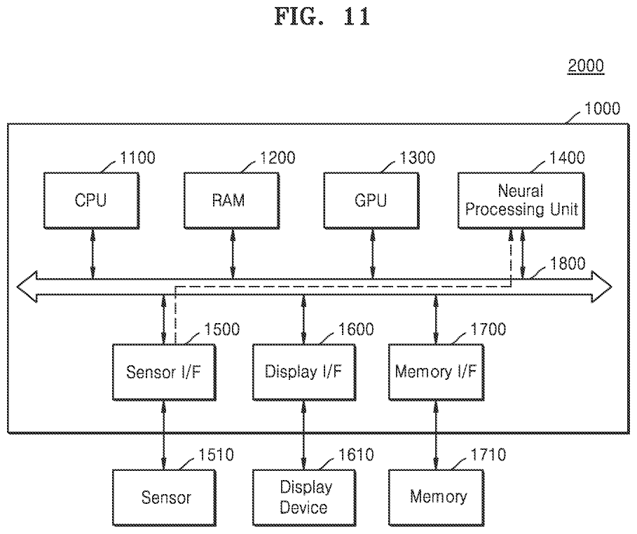

FIG. 11 is a block diagram illustrating an integrated circuit 1000 and an apparatus 2000 including the same, according to an embodiment.

The apparatus 2000 may include the integrated circuit 1000 and elements (for example, a sensor 1510, a display device 1610, and a memory 1710) connected to the integrated circuit 1000. The apparatus 2000 may be an apparatus which processes data based on a neural network. For example, the apparatus 2000 may include a mobile device such as a process simulator, a smartphone, a game machine, or a wearable device.

The integrated circuit 1000 according to an embodiment may include a CPU 1100, RAM 1200, a GPU 1300, a neural processing unit 1400, a sensor interface 1500, a display interface 1600, and a memory interface 1700. In addition, the integrated circuit 1000 may further include other general-use elements such as a communication module, a digital processor (DSP), and a video module, and the elements (for example, the CPU 1100, the RAM 1200, the GPU 1300, the neural processing unit 1400, the sensor interface 1500, the display interface 1600, and the memory interface 1700) of the integrated circuit 1000 may transfer and receive data therebetween through a bus 1800. In an embodiment, the integrated circuit 1000 may include an application processor. In an embodiment, the integrated circuit 1000 may be implemented as a system on chip (SoC).

The CPU 1100 may control an overall operation of the integrated circuit 1000. The CPU 1100 may include one processor core (single core), or may include a plurality of processor cores (multi-core). The CPU 1100 may process or execute data and/or programs stored in the memory 1710. In an embodiment, the CPU 1100 may execute the programs stored in the memory 1710, and thus, may control a function of the neural processing unit 1400.

The RAM 1200 may temporarily store programs, data, and/or instructions. According to an embodiment, the RAM 1200 may be implemented as DRAM or SRAM. The RAM 1200 may temporarily store data (for example, image data) which is input/output through the sensor interface 1500 and the display interface 1600 or is generated by the GPU 1300 or the CPU 1100.

In an embodiment, the integrated circuit 1000 may further include ROM. The ROM may store data and/or programs used continuously. The ROM may be implemented as erasable programmable ROM (EPROM) or electrically erasable programmable ROM (EEPROM).

The GPU 1300 may perform image processing on image data. For example, the GPU 1300 may perform image processing on the image data received through the sensor interface 1500. The image data processed by the GPU 1300 may be stored in the memory 1710, or may be provided to the display device 1610 through the display interface 1600. The image data stored in the memory 1710 may be provided to the neural processing unit 1400.

The sensor interface 1500 may interface with data (for example, image data, sound data, etc.) input from the sensor 1510 connected to the integrated circuit 1000.

The display interface 1600 may interface with data (for example, an image) output to the display device 1610. The display device 1610 may output an image or data of an image by using a display such as a liquid crystal display (LCD) display or an active matrix organic light emitting diode (AMOLED) display.

The memory interface 1700 may interface with data, input from the memory 1710 outside the integrated circuit 1000, or data output to the memory 1710. According to an embodiment, the memory 1710 may be implemented as a volatile memory, such as DRAM or SRAM, or a non-volatile memory such as resistive RAM (ReRAM), PRAM, or NAND flash memory. The memory 1710 may be implemented as a memory card (a multimedia card (MMC), an embedded multi-media card (eMMC), an SD card, or a micro SD card).

The neural network device 110 described above with reference to FIG. 1 may be applied as the neural processing unit 1400. The neural processing unit 1400 may receive and learn process simulation data and measurement data from the sensor 1510 through the sensor interface 1500 to perform a process simulation.

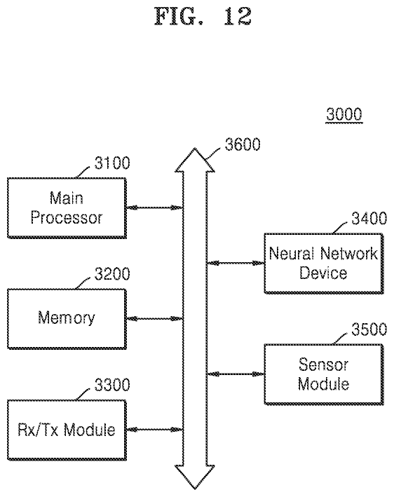

FIG. 12 is a block diagram illustrating a system 3000 including a neural network device, according to an embodiment.

Referring to FIG. 12, the system 3000 may include a main processor 3100, a memory 3200, a communication module 3300, a neural processing device 3400, and a simulation module 3500. The elements of the system 3000 may communicate with one another through a bus 3600.

The main processor 3100 may control an overall operation of the system 3000. For example, the main processor 3100 may include a CPU. The main processor 3100 may include one core (single core), or may include a plurality of cores (multi-core). The main processor 3100 may process or execute data and/or programs stored in the memory 1710. For example, the main processor 3100 may execute programs stored in the memory 3200. As a result, the main processor 3100 may perform control so that the neural processing device 3400 drives a neural network and may perform control so that the neural processing device 3400 generates a process simulation model based on inductive transfer learning.

The communication module 3300 may include various wired or wireless interfaces for communicating with an external device. The communication module 3300 may receive a learned target neural network from a server, and moreover, may receive a sensor correspondence network generated through reinforcement learning. The communication module 3300 may include a communication interface accessible to local area network (LAN), wireless local area network (WLAN) such as wireless fidelity (Wi-Fi), wireless personal area network (WPAN) such as Bluetooth, and a mobile cellular network such as wireless universal serial bus (USB), Zigbee, near field communication (NFC), radio-frequency identification (RFID), power line communication (PLC), 3^{rd} generation (3G), 4^{th} generation (4G), or long term evolution (LTE).

The simulation module 3500 may process various kinds of input/output data for simulating a semiconductor process. For example, the simulation module 3500 may include equipment for measuring a manufactured semiconductor and may provide measured real data to the neural processing device 3400.

The neural processing device 3400 may perform a neural network operation based on process data generated through the simulation module 3500. Examples of process data include a process parameter, a voltage-current characteristic, and doping profiles. The process simulation system 100 described above with reference to figures from FIG. 1 to FIG. 11 may be applied as the neural processing device 3400. The neural processing device 3400 may generate a feature map based on an inductive transfer learning network which has classified and learned weight values of data received from the simulation module 3500, instead of processed data. The neural processing device 3400 may apply the feature map as an input of a hidden layer of a target neural network, thereby driving the target neural network. Therefore, a process simulation data processing speed and accuracy of the system 3000 may increase.

A method of generating a process simulation model based on simulation data and measurement data, according to an embodiment, may effectively and quickly correct a difference between the simulation data and the measurement data and may enhance the accuracy of a processing result of the process simulation model.

The process simulation model according to an embodiment may effectively and quickly correct a difference between the simulation data and the measurement data and may effectively correct a data difference between a previous-generation process and a current-generation process and an inter-process data difference or an equipment-based data difference in the same generation process.

An apparatus according to the embodiments may include a processor, a memory storing and executing program data, a permanent storage such as a disk drive, a communication port for communication with an external device, a user interface device such as a touch panel, keys or buttons, and the like. Methods implemented as software modules or algorithms may be stored as computer-readable codes or program instructions, executable by the processor, in a computer-readable recording medium. Here, the computer-readable recording medium may include a magnetic storage medium (for example, ROM, RAM, floppy disk, hard disk, etc.) and an optical readable medium (for example, CD-ROM, digital versatile disk (DVD), etc.). The computer-readable recording medium may be distributed to computer systems connected to one another over a network, and a computer-readable code may be stored and executed therein based on a distributed scheme. A medium may be readable by a computer, may be stored in a memory, and may be executed by a processor.

The embodiments may be implemented with functional blocks and various processing steps. The functional blocks may be implemented as a various number of hardware or/and software elements for executing certain functions. For example, the embodiments may use integrated circuits, such as a memory, a processor, a logic, and a lookup table, for executing various functions based on control by one or more microprocessors or various control devices. Like that elements may be executed as software programming or software elements, the embodiments may include various algorithms implemented by a data structure, processes, routines, or a combination of other programming elements and may be implemented in a programming or scripting language such as C, C++, Java, or an assembler. Functional elements may be implemented as algorithms executed by one or more processors. Also, the embodiments may use the related art, for an electronic environment setting, signal processing, and/or data processing.

While the teachings herein have been particularly shown and described with reference to embodiments thereof, it will be understood that various changes in form and details may be made therein without departing from the spirit and scope of the following claims.

1. A method of generating a simulation model based on simulation data and measurement data of a target, the method comprising:
classifying weight parameters, included in a pre-learning model learned based on the simulation data, as a first weight group and a second weight group based on a degree of significance;
retraining the first weight group of the pre-learning model based on the simulation data; and
training the second weight group of a transfer learning model based on the measurement data, wherein the transfer learning model includes the first weight group of the pre-learning model retrained based on the simulation data.

2. The method of claim 1, wherein
the classifying of the weight parameters comprises extracting the first weight group from the weight parameters based on sizes of the weight parameters.

3. The method of claim 1, wherein
the classifying of the weight parameters comprises sorting the weight parameters in ascending order thereof based on sizes of the weight parameters, generating a reference weight value based on a degree of variation of each of sizes of the sorted weight parameters, and classifying weight parameters, which are greater than or equal to the reference weight value, as the first weight group.

4. The method of claim 1, wherein
the retraining of the first weight group of the pre-learning model comprises initializing values of weight parameters included in the second weight group before retraining the first weight group.

5. The method of claim 1, wherein
the training of the second weight group of the transfer learning model comprises maintaining values of weight parameters of the first weight group learned in the pre-learning model and retraining weight parameters of the second weight group.

6. The method of claim 1, wherein
the training of the transfer learning model comprises normalizing values of weight parameters of the trained second weight group.

7. The method of claim 1, wherein
the target is a semiconductor process, and the simulation data comprises at least one of semiconductor process parameters and characteristic data of a semiconductor device manufactured based on the semiconductor process parameters, and
the characteristic data comprises at least one of a doping profile and a voltage-current characteristic of the semiconductor device.

8. The method of claim 7, wherein
the pre-learning model or the transfer learning model is configured to infer at least one of the doping profile and the voltage-current characteristic of the semiconductor device.

9. The method of claim 1, wherein
the transfer learning model comprises a first transfer learning model configured to infer a voltage-current characteristic of a semiconductor device and a second transfer learning model configured to infer a doping profile of the semiconductor device, by using semiconductor process parameters as inputs.

10. The method of claim 9, wherein
the training of the transfer learning model comprises inferring the voltage-current characteristic based on the first transfer learning model and generating the second transfer learning model based on a difference between the pre-learning model and the first transfer learning model.

11. A method of generating a simulation model based on simulation data and measurement data of a target, the method comprising:
generating a common model, learning a common feature of a first characteristic and a second characteristic based on simulation data, and generating a first pre-learning model inferring the first characteristic and a second pre-learning model inferring the second characteristic, based on the common model;
classifying weight parameters, included in the first pre-learning model, as a first weight group and a second weight group based on the first characteristic and a degree of association;
initializing weight parameters included in the second weight group and retraining the first pre-learning model and the second pre-learning model based on the first weight group and the simulation data;
retraining the second pre-learning model based on the second weight group and the simulation data;
training a first transfer learning model corresponding to the first pre-learning model based on the first weight group and measurement data of the first characteristic; and
training a second transfer learning model corresponding to the second pre-learning model based on the first transfer learning model.

12.-16. (canceled)

17. The method of claim 11, wherein
the training of the second transfer learning model comprises generating the second transfer learning model based on the first pre-learning model, variation data of a weight parameter of the first transfer learning model, and the second weight group of the second pre-learning model.

18. A neural network device, comprising:
a memory configured to store a neural network program; and
a processor configured to execute the neural network program stored in the memory, wherein
the processor is configured to execute the neural network program to classify weight parameters, included in a pre-learning model learned based on simulation data, as a first weight group and a second weight group based on a degree of significance, to retrain the first weight group of the pre-learning model based on the simulation data, and to train the second weight group of a transfer learning model based on measurement data, wherein the transfer learning model includes the first weight group of the pre-learning model retrained on the simulation data.

19. The neural network device of claim 18, wherein
the processor is configured to extract the first weight group from the weight parameters based on sizes of the weight parameters.

20. The neural network device of claim 18, wherein
the processor is configured to sort the weight parameters in ascending order thereof based on sizes of the weight parameters, to generate a reference weight value based on a degree of variation of each of sizes of the sorted weight parameters, and to classify weight parameters, which are greater than or equal to the reference weight value, as the first weight group.

21. The neural network device of claim 18, wherein
the processor is configured to initialize values of weight parameters included in the second weight group before retraining the first weight group.

22. The neural network device of claim 18, wherein
the processor is configured to maintain values of weight parameters of the first weight group learned in the pre-learning model and to train weight parameters of the second weight group.

23. The neural network device of claim 18, wherein
the processor is configured to normalize values of weight parameters of the trained second weight group.

24. The neural network device of claim 18, wherein
the simulation data comprises at least one of semiconductor process parameters and characteristic data of a semiconductor device manufactured based on the semiconductor process parameters, and
the characteristic data comprises at least one of a doping profile and a voltage-current characteristic of the semiconductor device.

25. The neural network device of claim 24, wherein
the pre-learning model or the transfer learning model is configured to infer at least one of the doping profile and the voltage-current characteristic of the semiconductor device.

26-27. (canceled)
